(19) United States
(12) Patent Application Publication
(10) Pub. No.: US 2025/0306275 A1
(43) Pub. Date: Oct. 2, 2025

(54) OPTICAL DETECTOR AND CHIP

(71) Applicant: SILITH TECHNOLOGY (SUZHOU) CO., LTD., Shanghai (CN)

(72) Inventors: Xiaojun SHI, Shanghai (CN); Yuxuan CHEN, Shanghai (CN); Ke ZHANG, Shanghai (CN)

(73) Assignee: SILITH TECHNOLOGY (SUZHOU) CO., LTD., Shanghai (CN)

(21) Appl. No.: 19/021,319

(22) Filed: Jan. 15, 2025

(30) Foreign Application Priority Data
Mar. 29, 2024 (CN) 202410370051.7

(51) Int. Cl. G02B 6/122; H10F 77/40

(52) U.S. Cl. CPC G02B 6/1228; H10F 77/413

(57) ABSTRACT

Optical detector includes photoelectric conversion unit, first and second spot-size conversion units, photoelectric conversion unit includes slab waveguide and absorption zone; both first and second spot-size conversion units include coupling waveguide and multimode interference structure in contact connection; one end of multimode interference structure, away from coupling waveguide, is in contact connection with slab waveguide; extension line of absorption zone in length direction falls on part surface of multimode interference structure without falling on surface of coupling waveguide. Incident light and emergent light are not on same straight line due to self-imaging effect of multimode interference structure, part of reflected light and transmitted light enter coupling waveguide, reducing reflection and transmission of light; maximum coupling efficiency can be selected by changing size of multimode interference structure, ensuring responsivity of optical detector, and solving problem of how to reduce reflection and transmission of light in optical detector while ensuring responsivity.

### CROSS-REFERENCE TO RELATED DISCLOSURE

This disclosure claims the priority benefit of China patent serial no. 202410370051.7, filed on Mar. 29, 2024. The entirety of the above-mentioned patent disclosure is hereby incorporated by reference herein and made a part of this specification.

### BACKGROUND

### Technical Field

The present disclosure relates to the technical field of optical devices, and in particular to an optical detector and a chip.

### Description of Related Art

As a class of semiconductor devices being able to convert detected light into an electrical signal, an optical detector has an important application in a plurality of fields, including image sensing, data communication, remote control, environmental monitoring, and more. With development of an integrated technology, a technology of silicon photonics is compatible with a CMOS technology, and having a plurality of advantages including a mature process and a high integration level, which is able to meet a plurality of requirements including high integration and low cost for a photoelectron device, wherein a Si-based Ge photodetector is a core device to achieve a photoelectric conversion.

A responsivity of the optical detector is an important indicator for determining the performance of the optical detector. Currently, a plurality of technologies have been adopted to ensure that the responsivity of the optical detector meets a requirement, including a single-mode waveguide coupling, a quasi-tapered waveguide type lateral coupling, a multimode interferometer coupling, and more.

However, in the prior art, an existing coupling mode is not able to reduce reflection when coupling light into the optical detector, and a part of the light not being converted into photocurrent will be transmitted back to a structure of the optical detector, which will affect a coupling efficiency of the optical detector to a certain extent.

### SUMMARY

An object of the present disclosure is providing an optical detector and a chip, in order to solve the problem of how to reduce both reflection and transmission of the light in the optical detector while ensuring the responsivity of the optical detector.

To solve the above technical problem, the present disclosure provides an optical detector, comprising a photoelectric conversion unit, a first spot-size conversion unit and a second spot-size conversion unit; the photoelectric conversion unit comprises a slab waveguide and an absorption zone stacked sequentially from bottom up, and the absorption zone covers a part surface of the slab waveguide; the first spot-size conversion unit and the second spot-size conversion unit are located respectively at two ends of the photoelectric conversion unit in a length direction, while both the first spot-size conversion unit and the second spot-size conversion unit comprise a coupling waveguide and a multimode interference structure in a contact connection; an end of the multimode interference structure away from the coupling waveguide is in a contact connection with the slab waveguide; an extension line of the absorption zone in the length direction passes through a part surface of the multimode interference structure, without crossing a surface of the coupling waveguide.

Preferably, the absorption zone has a length less than or equal to a length of the slab waveguide, and the absorption zone is arranged in a middle of the slab waveguide in both a width direction and the length direction.

Preferably, the first spot-size conversion unit and the second spot-size conversion unit are arranged in a central symmetry by taking a center of the absorption zone as a center of the central symmetry.

Preferably, the first spot-size conversion unit and the second spot-size conversion unit are arranged on a same side of the absorption zone along the length direction, and arranged symmetrically by taking a centerline along the width direction of the slab waveguide as a symmetric axis.

Preferably, an offset of a centerline along the length direction of the coupling waveguide relative to a centerline along a length direction of the multimode interference structure is less than half of a width of the multimode interference structure.

Preferably, the optical detector further comprises a substrate, a lower cladding layer, and an upper cladding layer; the lower cladding layer is located on a surface of the substrate; the photoelectric conversion unit, the first spot-size conversion unit, and the second spot-size conversion unit are all located on a surface of the lower cladding layer; while the upper cladding layer covers the photoelectric conversion unit, the first spot-size conversion unit, and the second spot-size conversion unit.

Preferably, the first spot-size conversion unit, the second spot-size conversion unit, and the slab waveguide all have a thickness of 200 nm-250 nm.

Preferably, the multimode interference structure has a length of 15-200 μm and a width of 1-8 μm.

Preferably, the length of the absorption zone is 5-80 μm, and the length of the slab waveguide is 5-80 μm; while a difference between the length of the absorption zone and the length of the slab waveguide is not greater than 2 μm.

Preferably, the absorption zone is partially embedded in the slab waveguide, and a depth of the absorption zone embedded in the slab waveguide is less than 150 nm.

In order to solve the technical problem stated above, the present disclosure further provides a chip, comprising the optical detector stated above.

The optical detector and the chip provided by the present disclosure, comprises a photoelectric conversion unit, a first spot-size conversion unit and a second spot-size conversion unit; the photoelectric conversion unit comprises a slab waveguide and an absorption zone which are stacked sequentially from bottom up, and the absorption zone covers a part surface of the slab waveguide; the first spot-size conversion unit and the second spot-size conversion unit are each located at one end of the photoelectric conversion unit in a length direction, while both the first spot-size conversion unit and the second spot-size conversion unit comprise a coupling waveguide and a multimode interference structure which are in contact connection; an end of the multimode interference structure away from the coupling waveguide is in contact connection with the slab waveguide; an extension line of the absorption zone in the length direction passes through a part surface of the multimode interference structure, without intersecting a surface of the coupling waveguide. Since the coupling waveguide and the absorption zone located at either end of the multimode interference structure are staggered in the length direction, and self-imaging effect of the multimode interference structure makes an incident light and an emergent light not on a same straight line, thus only part of reflected light and transmitted light from the photoelectric conversion unit can enter the coupling waveguide, thereby reducing reflection and transmission of the light; meanwhile, light field distribution inside the photoelectric conversion unit can be adjusted by changing a size of the multimode interference structure, so that it is able to select a maximum coupling efficiency, further ensure the responsivity of the optical detector, and solve the problem of how to reduce reflection and transmission of the light in the light detector while ensuring the responsivity.

### BRIEF DESCRIPTION OF THE DRAWINGS

FIG. 1 illustrates a schematic structural diagram on an optical detector according to an embodiment of the present disclosure;

FIG. 2 illustrates a schematic structural diagram on another optical detector according to an embodiment of the present disclosure;

FIG. 3 illustrates schematic structural diagram on a first spot-size conversion unit according to an embodiment of the present disclosure;

FIG. 4 illustrates a schematic cross-sectional view on an optical detector at A1-A1 according to an embodiment of the present disclosure;

FIG. 5 illustrates a schematic cross-sectional view on an optical detector at A2-A2 according to an embodiment of the present disclosure;

FIG. 6 illustrates a schematic cross-sectional view on an optical detector at A3-A3 according to an embodiment of the present disclosure;

FIG. 7 illustrates a schematic cross-sectional view on an optical detector at B-B according to an embodiment of the present disclosure;

FIG. 8 illustrates a schematic cross-sectional view on another optical detector at A1-A1 according to an embodiment of the present disclosure;

FIG. 9 illustrates a schematic cross-sectional view on a third optical detector at A1-A1 according to an embodiment of the present disclosure;

Wherein, 110—first spot—size conversion unit; 111—first coupling waveguide; 112—first multimode interference structure; 110′—second spot—size conversion unit; 111′—second coupling waveguide; 112′—second multimode interference structure; 120—photoelectric conversion unit; 121—slab waveguide; 122—absorption zone; 130—lower cladding layer; 140—substrate; 150—upper cladding layer.

### DESCRIPTION OF THE EMBODIMENTS

An optical detector and a chip provided by the present disclosure will be further described in detail below with reference to the accompanying drawings and specific embodiments. It should be noted that the drawings all adopt a very simplified form and use a non-precise ratio, which is used to conveniently and clearly assist in explaining the purpose of the embodiments of the present invention only. In addition, the structure shown in the drawings is usually part of an actual structure. In particular, each of the figures shows different emphasis, and sometimes different proportions are adopted.

It should be noted that the terms “first”, “second” and the like in the specification, claims, and drawings of the present disclosure are used to distinguish similar objects, so as to describe the embodiments of the present disclosure, instead of used to describe a specific order or sequence, and it should be understood that the structure used in this way can be interchanged under appropriate circumstances. In addition, the terms “include” and “have” and any variations thereof are intended to cover a non-exclusive inclusion, for example, a process, method, system, product, or device that comprises a series of steps or units is not necessarily limited to those steps or units that are clearly listed, but may include other steps or units that are not clearly listed or inherent to these processes, methods, products, or devices.

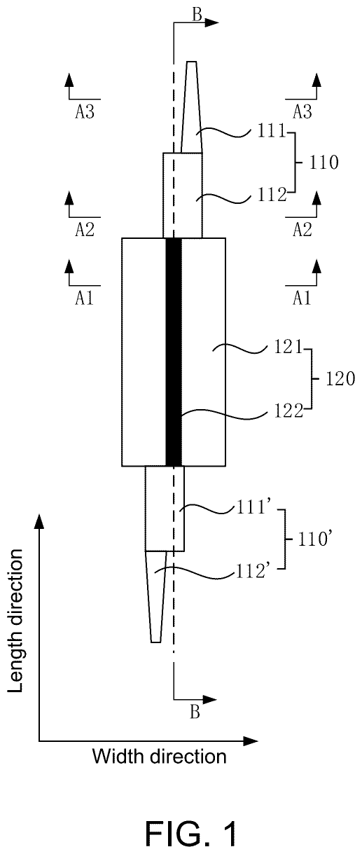

The present disclosure provides an optical detector, in an embodiment, shown as FIG. 1, comprising a photoelectric conversion unit 120, a first spot-size conversion unit 110 and a second spot-size conversion unit 110′; the photoelectric conversion unit 120 comprises a slab waveguide 121 and an absorption zone 122, which are stacked sequentially from bottom up, and the absorption zone 122 covers a part surface of the slab waveguide 121; the first spot-size conversion unit 110 and the second spot-size conversion unit 110′ are each located at one end of the photoelectric conversion unit 120 in a length direction, while the first spot-size conversion unit 110 comprises a first coupling waveguide 111 and a first multimode interference structure 112 which are in contact connection; the second spot-size conversion unit 110′ comprises a second coupling waveguide 111′ and a second multimode interference structure 112′ which are in contact connection; an end of the first (second) multimode interference structure 112 (112′) away from the first (second) coupling waveguide 111(111′) is in contact connection with the slab waveguide 121; an extension line of the absorption zone 122 in the length direction passes through a part surface of the first (second) multimode interference structure 112 (112′), without intersecting a surface of the first (second) coupling waveguide 111 (111′).

The optical detector provided in the present embodiment, since the coupling waveguide 111 (111′) and the absorption zone 122 located at either end of the multimode interference structure 112 (112′) are staggered in the length direction, and self-imaging effect of the multimode interference structure 112 (112′) makes an incident light and an emergent light not on a same straight line, thus only part of reflected light and transmitted light from the photoelectric conversion unit 120 can enter the coupling waveguide 111 (111′), thereby reducing reflection and transmission of the light; meanwhile, light field distribution inside the photoelectric conversion unit 120 can be adjusted by changing a size of the multimode interference structure 112 (112′), so that it is able to select a maximum coupling efficiency, further ensure the responsivity of the optical detector, and solve the problem of how to reduce reflection and transmission of the light in the light detector while ensuring the responsivity.

In an actual application process, the slab waveguide 121 may be a silicon slab waveguide; the absorption zone 122 may be a germanium absorption zone; the coupling waveguide 111 (111′) may be a coupled silicon waveguide; and the multimode interference structure 112 (112′) may be a silicon waveguide multimode interferometer. Of course, in a plurality of other embodiments, a material of the slab waveguide 121 may also be an oxide of silicon, a nitride of silicon, and more; a material of the absorption region 122 may also be indium phosphide, and more; a material of the coupling waveguide may also be a plurality of materials having a refractive index higher than that of the silicon oxide, including silicon nitride, silicon oxynitride, lithium niobate, indium phosphide, aluminum oxide, a polymer, and more. A person skilled in the art can reasonably select the material of each structure through an actual requirement, which is not limited in the present disclosure.

In an actual application process, the coupling waveguide 111 (111′) may be a slab waveguide or a tapered waveguide, wherein a changing curve of the tapered waveguide may achieve a size conversion by adopting a plurality of strategies including linear, exponential, parabola, a Bezier curve, a SiN curve, an Euler curve, a sub-wavelength structure, and a combination thereof.

Further, in the present embodiment, the absorption zone 122 has the length less than or equal to the length of the slab waveguide 121, and locates in a middle of the slab waveguide 121 in both the width direction and the length direction. In this way, when the first spot-size conversion unit 110 and the second spot-size conversion unit 110′ in a structure shown in FIG. 1 are arranged in central symmetry by taking a center of the absorption zone 122 as a center of the central symmetry, the multimode interference structure 112 (112′) in connection with the slab waveguide 121 can be all in connection with the slab waveguide 121, so as to facilitate to reduce a volume of the optical detector.

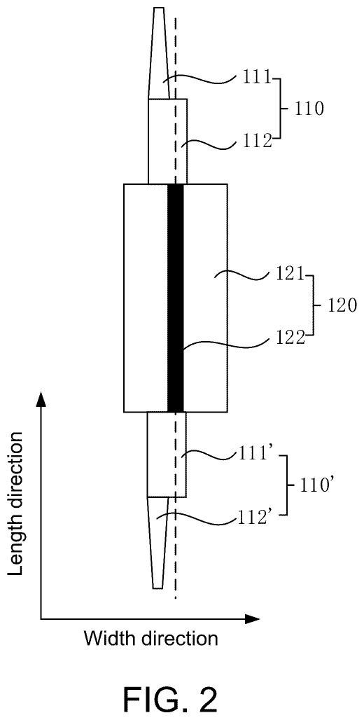

In another embodiment, shown as FIG. 2, the first spot-size conversion unit 110 and the second spot-size conversion unit 110′ are arranged on a same side of the length direction of the absorption zone 122, and symmetrically arranged by taking a centerline along the width direction of the slab waveguide 121 as a symmetric axis. In this way, it is not necessary to strictly require that the absorption region 122 be located at a central position of the slab waveguide 121, while achieving in a same way, that only a part of the light reflected back from the photoelectric conversion unit and the transmitted light can enter the coupling waveguide, thereby reducing the reflection and transmission of the light.

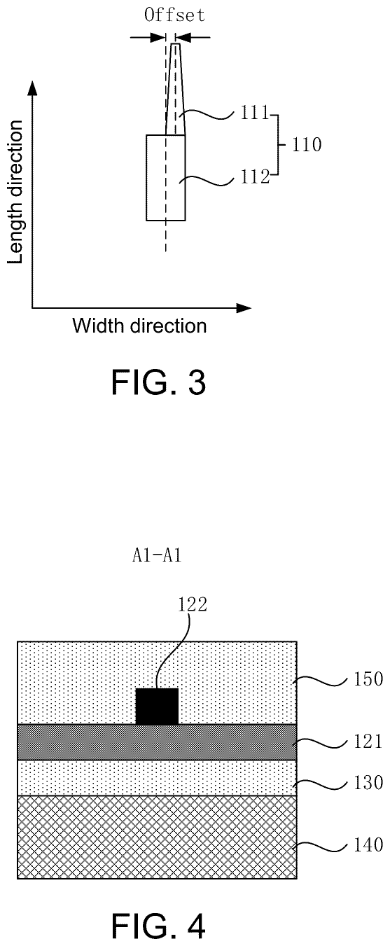

In order to ensure that the light input by the coupling waveguide 111 (111′) can totally enter the multimode interference structure 112 (112′), and the reflected light in the multimode interference structure 112 (112′) enters the coupling waveguide 111 (111′) as little as possible, in the present embodiment, shown as FIG. 3, an offset of a centerline in the length direction of the coupling waveguide 111 (111′) relative to a centerline in a length direction of the multimode interference structure 112 (112′) is less than half of the width of the multimode interference structure 112 (112′).

Preferably, an input end and an output end of the multimode interference structure 112 (112′) are arranged in a central symmetry about a center of the multimode interference structure 112 (112′), that is, a connection position between the coupling waveguide 111 (111′) and the multimode interference structure 112 (112′) is arranged in a central symmetry about the center of the multimode interference structure 112 (112′) with a connection position between a vertical projection of the absorption zone 122 at the slab waveguide 121 and the multimode interference structure 112 (112′). In such a way, it is possible to fully utilize the self-imaging effect of the multimode interference structure 112 (112′).

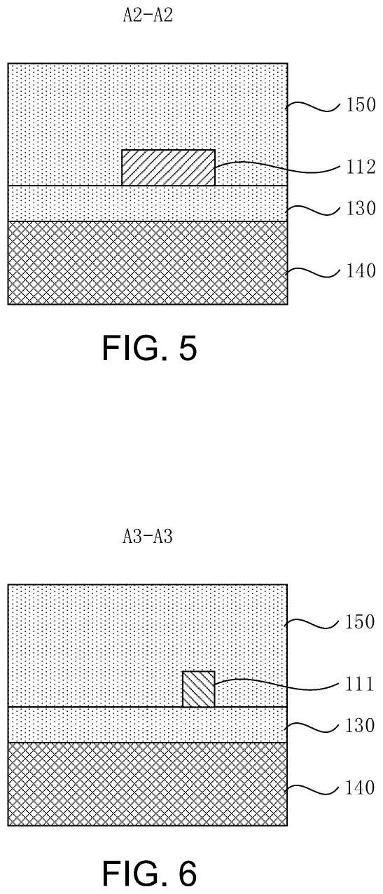

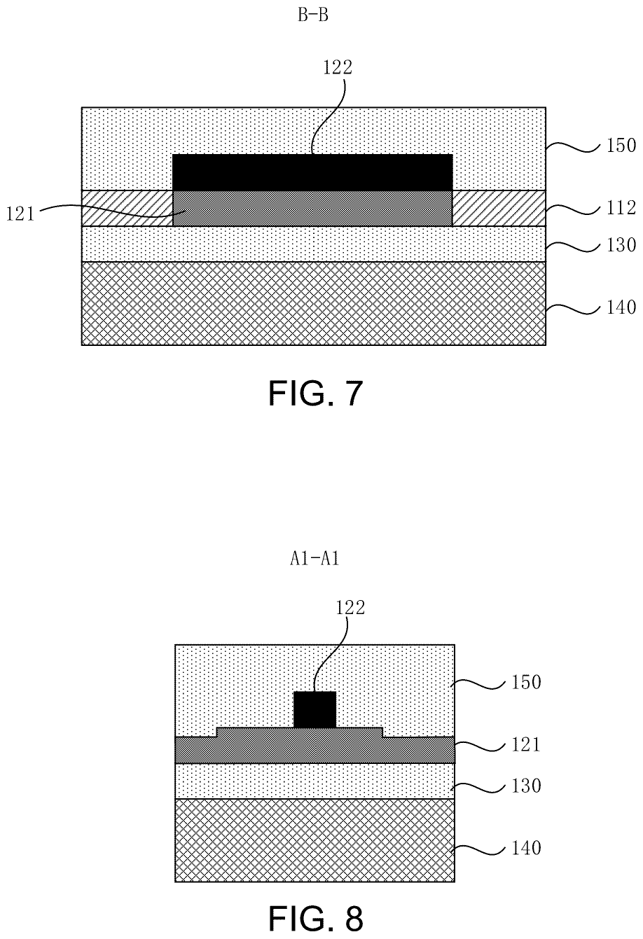

In a practical application, in order to facilitate manufacturing the optical detector, and in order to protect the photoelectric conversion unit 120, the first spot-size conversion unit 110 and the second spot-size conversion unit 110′, shown as FIG. 4 to FIG. 7, the optical detector further comprises a substrate 140, a lower cladding layer 130, and an upper cladding layer 150; the lower cladding layer 130 is located on a surface of the substrate 140; the photoelectric conversion unit 120, the first spot-size conversion unit 110 and the second spot-size conversion unit 110′ are all located on a surface of the lower cladding layer 130; while the upper cladding layer 150 covers the photoelectric conversion unit 120, the first spot-size conversion unit 110 and the second spot-size conversion unit 110′. In such a way, the photoelectric conversion unit 120, the first spot-size conversion unit 110 and the second spot-size conversion unit 110′ are respectively surrounded by the upper cladding layer 150 and the lower cladding layer 130, thereby ensuring that a device will not be damaged.

In a manufacturing process of the optical detector, a process step thereof mainly comprises: providing a substrate 140, and depositing a lower cladding layer 130 on the substrate 140; forming a silicon waveguide layer on the lower cladding layer 130, and forming the coupling waveguide 111 (111′), the multimode interference structure 112 (112′), and the slab waveguide 121 in different regions of the silicon waveguide layer respectively, by means of a photolithography or etching process; forming the absorption zone 122 on the slab waveguide 121; and depositing the upper cladding layer 150. Of course, in an actual manufacturing, a person skilled in the art may reasonably select a process and a plurality of parameters according to a structure and process requirement of the optical detector, and no more details are described herein.

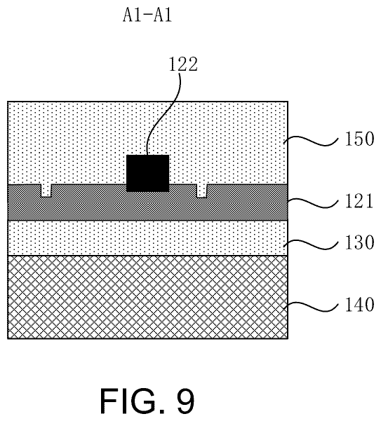

Further, in order to reduce manufacturing difficulty and cost of the process, shown as FIG. 8, the slab waveguide 121 may be partially etched, that is, there may be a part of the surface uneven. Shown as FIG. 9, the absorption zone 122 is partially embedded in the slab waveguide 121, and a depth of the absorption zone 122 embedded in the slab waveguide 121 is less than 150 nm.

In a specific embodiment, a thickness of the first spot-size conversion unit 110, a thickness of the second spot-size conversion unit 110′, and a thickness of the slab waveguide 121 are all between 200 nm and 250 nm, for example, 220 nm; a length of the multimode interference structure 122 is 15-200 μm, a width of the multimode interference structure 122 is 1-8 μm, for example, a length may be 45.3 μm, and a width may be 3 μm; while an offset of a centerline in the length direction of the coupling waveguide 111 (111′) relative to a centerline of the multimode interference structure 112 (112′) may specifically be 0.8 μm. The length of the absorption zone 122 is 5-80 μm, the length of the slab waveguide 121 is 5-80 μm, a difference between the length of the absorption zone 122 and the length of the slab waveguide 121 is no more than 2 μm, and specifically, for example, the length of the absorption zone 122 and the length of the slab waveguide 121 are both 9 μm.

The optical detector having such a size of structure, in a practical application, light enters from the first coupling waveguide 111 in the first spot-size conversion unit 110, before being converted into a single-mode waveguide with a larger spot-size from a single-mode waveguide with a smaller spot-size; then after passing through the first multimode interference structure 112 and generating a mirror mode, the light enters the photoelectric conversion unit from one end of the first multimode interference structure 112 close to the slab waveguide 121; the absorption zone 122 absorbs the light and generates a photocurrent. For a part of the light not being absorbed, wherein a portion thereof enters the second multimode interference structure 112′ in the second spot-size conversion unit 110′, and another portion thereof is reflected back to the first multimode interference structure 112 in the first mode spot conversion unit 110; however, due to the self-imaging effect of the multimode interference structure 112/112′, since the input light and the output light of the multimode interference structure 112/112′ are not following a same straight line, only a small portion of the reflected light can enter the first coupling waveguide 111, and a small portion of the transmitted light can enter the second coupling waveguide 111′, thereby both the reflection and the transmission of the light are reduced and the performance of the optical detector is improved.

Specifically, the optical detector with such a structural size has a response degree about 1 A/W, and the light reflection at the input end has reduced to −38 dB from −35 dB of an existing optical detector, and the light transmission at the output end has reduced from −33 dB to −40 dB, thus a performance has been significantly improved.

It should be noted that, although in the embodiment stated above, the first spot-size conversion unit 110 is taken as a light input end, and the second spot-size conversion unit 110′ is taken as a light output end, in an actual application, it is also possible to take the first spot-size conversion unit 110 as the light output end, and the second spot-size conversion unit 110′ as the light input end, that is, both spot-size conversion units are taken as the light input end and the light output end respectively, without restricting a propagation direction of the light.

The optical detector and the chip provided by the present embodiment, comprises a photoelectric conversion unit 120, a first spot-size conversion unit 110 and a second spot-size conversion unit 110′; the photoelectric conversion unit 120 comprises a slab waveguide 121 and an absorption zone 122 which are stacked sequentially from bottom up, and the absorption zone 122 covers a part surface of the slab waveguide 121; the first spot-size conversion unit 110 and the second spot-size conversion unit 110′ are each located at one end of the photoelectric conversion unit 120 in a length direction, while both the first spot-size conversion unit 110 and the second spot-size conversion unit 110′ comprise a coupling waveguide and a multimode interference structure which are in contact connection; an end of the multimode interference structure away from the coupling waveguide is in contact connection with the slab waveguide 121; an extension line of the absorption zone 122 in the length direction passes through a part surface of the multimode interference structure, without intersecting a surface of the coupling waveguide. Since the coupling waveguide and the absorption zone 122 located at either end of the multimode interference structure are staggered in the length direction, and self-imaging effect of the multimode interference structure makes the incident light and the emergent light not on a same straight line, thus only part of the reflected light and transmitted light from the photoelectric conversion unit can enter the coupling waveguide, thereby reducing reflection and transmission of the light; meanwhile, light field distribution inside the photoelectric conversion unit 120 can be adjusted by changing a size of the multimode interference structure, so that it is able to select a maximum coupling efficiency, further ensure the responsivity of the optical detector, and solve the problem of how to reduce reflection and transmission of the light in the light detector while ensuring the responsivity.

It should be noted that the embodiments in the present specification are described in a progressive manner, each embodiment focuses on differences from other embodiments, and the same or similar parts between the embodiments may refer to each other; in addition, different parts between the embodiments may also be used in combination with each other, which is not limited in the present disclosure

The above description is only a description of the preferred embodiments of the present disclosure, instead of limiting the scope of the present disclosure, and any changes and modifications made by those of ordinary skill in the art according to the above disclosure shall fall within the scope of protection of the claims.

What is claimed is:

1. An optical detector, comprising a photoelectric conversion unit, a first spot-size conversion unit and a second spot-size conversion unit; wherein the photoelectric conversion unit comprises a slab waveguide and an absorption zone stacked sequentially from bottom up, and the absorption zone covers a part surface of the slab waveguide; the first spot-size conversion unit and the second spot-size conversion unit are located respectively at two ends of the photoelectric conversion unit in a length direction, while both the first spot-size conversion unit and the second spot-size conversion unit comprise a coupling waveguide and a multimode interference structure in a contact connection; an end of the multimode interference structure away from the coupling waveguide is in a contact connection with the slab waveguide; an extension line of the absorption zone in the length direction passes through a part surface of the multimode interference structure, without crossing a surface of the coupling waveguide.

2. The optical detector according to claim 1, wherein the absorption zone has a length less than or equal to a length of the slab waveguide, and the absorption zone is arranged in a middle of the slab waveguide in both a width direction and the length direction.

3. The optical detector according to claim 1, wherein the first spot-size conversion unit and the second spot-size conversion unit are arranged in central symmetry by taking a center of the absorption zone as a center of the central symmetry.

4. The optical detector according to claim 1, wherein the first spot-size conversion unit and the second spot-size conversion unit are arranged on a same side of the length direction of the absorption zone, and symmetrically arranged by taking a centerline along the width direction of the slab waveguide as a symmetric axis.

5. The optical detector according to claim 1, wherein an offset of a centerline in a length direction of the coupling waveguide relative to a centerline in a length direction of the multimode interference structure is less than half of a width of the multimode interference structure.

6. The optical detector according to claim 1, wherein the optical detector further comprises a substrate, a lower cladding layer, and an upper cladding layer; the lower cladding layer is located on a surface of the substrate; the photoelectric conversion unit, the first spot-size conversion unit, and the second spot-size conversion unit are all located on a surface of the lower cladding layer; while the upper cladding layer covers the photoelectric conversion unit, the first spot-size conversion unit, and the second spot-size conversion unit.

7. The optical detector according to claim 1, wherein the first spot-size conversion unit, the second spot-size conversion unit, and the slab waveguide all have a thickness of 200 nm-250 nm.

8. The optical detector according to claim 1, wherein the multimode interference structure has a length of 15-200 μm and a width of 1-8 μm.

9. The optical detector according to claim 1, wherein a length of the absorption zone is 5-80 μm, and a length of the slab waveguide is 5-80 μm; while a difference between the length of the absorption zone and the length of the slab waveguide is not greater than 2 μm.

10. The optical detector according to claim 1, wherein the absorption zone is partially embedded in the slab waveguide, and a depth of the absorption zone embedded in the slab waveguide is less than 150 nm.

11. A chip, comprising the optical detector according to claim 1.

12. The chip according to claim 11, wherein a length of the absorption zone is less than or equal to a length of the slab waveguide, and the absorption zone is arranged in a middle of the slab waveguide in both a width direction and the length direction.

13. The chip according to claim 11, wherein the first spot-size conversion unit and the second spot-size conversion unit are arranged in central symmetry by taking a center of the absorption zone as a center of the central symmetry.

14. The chip according to claim 11, wherein the first spot-size conversion unit and the second spot-size conversion unit are arranged on a same side of the length direction of the absorption zone, and symmetrically arranged by taking a centerline along the width direction of the slab waveguide as a symmetric axis.

15. The chip according to claim 11, wherein the optical detector further comprises a substrate, a lower cladding layer, and an upper cladding layer; the lower cladding layer is located on a surface of the substrate; the photoelectric conversion unit, the first spot-size conversion unit, and the second spot-size conversion unit are all located on a surface of the lower cladding layer; while the upper cladding layer covers the photoelectric conversion unit, the first spot-size conversion unit, and the second spot-size conversion unit.
